(19) United States
(12) Patent Application Publication
(10) Pub. No.: US 2008/0151479 A1
(43) Pub. Date: Jun. 26, 2008

(54) Structure of one-piece-form 3-dimensional bezel and manufacturing method thereof

(75) Inventor: Wen-Chin Tsai, Jhubei City (TW)

Correspondence Address: ABELMAN, FRAYNE & SCHWAB, 666 THIRD AVENUE, 10TH FLOOR, NEW YORK, NY, 10017, US

(73) Assignee: Jochu Technology Co., Ltd.

(21) Appl. No.: 11/823,448

(22) Filed: Jun. 26, 2007

(30) Foreign Application Priority Data
Dec. 20, 2006 (TW) 95148027
Apr. 10, 2007 (TW) 96112431

(51) Int. Cl. H05K 5/02

(52) U.S. Cl. 361/681

(57) ABSTRACT

A one-piece-form 3-dimentional bezel and its manufacturing method are disclosed here. The present invention utilizes a 3-dimentional frame element with one-piece-form rivet portions on a top side and on a lateral side and a 3-dimentional frame element with one-piece-form riveting holes on a top side and a lateral side to rivet 3-dimentional frame elements with each other and to complete the assemble by punching. The present invention is not necessary to utilize extra assembling processes, such as soldering, melting, adhesive or gluing process, to joint frame elements and is only to utilize the normal punching equipments to form the present one-piece-form 3-dimentional bezel.

### BACKGROUND OF THE INVENTION

1. Field of the Invention

The present invention relates to a bezel of a liquid crystal display and, more especially, to a one-piece-form 3-dimentional bezel of the liquid crystal display and its manufacturing method.

2. Description of the Prior Art

Generally, the prior bezel of the plane display is formed by directly one-step punching the metal material to form the one-piece-form bezel. Owing to the bigger size of the bezel, it needs the punching equipment and the mold with the bigger size and specification for one-step punching so as the cost will be increased because of the punching equipment and the mold. Besides, the mold is bulky, the operation is difficult and the waste material of the punching step is much. The structure of the one-piece-form bezel is stronger; however, the cost is corresponding increasing.

Hence, there are usually using a plurality of frame elements to constitute a rectangle bezel for fixing the panel and the metal bezel or frame of the backlight module. Referring to FIG. 1A, FIG. 1B, FIG. 1C, FIG. 1D and FIG. 1E, those are partial schematic diagrams of the bezel structure of the display panel of the Taiwan Patent Issued No. M285175. The disclosed bezel is composed of a plurality of frame elements and has a containing space 1a

Following the foregoing description, frame elements 10 are jointed with each other at the edge. At the edge of frame element, there are respectively formed a joint surface 11 with a corresponding reduced thickness. A semicircle concave portion 11a and a protruding portion 11b are formed on the joint surface 11. Further, there are respectively corresponding arranged a mortise 12a and a tenon 12b for joint surfaces 11 to align and to tenon with each other. At the outside edge of the frame element 10, a vertical portion 13 is formed to around and to constitute a containing space 1a. In the prior art, the disclosed bezel structure must be completed by utilizing the welding step, the solvent, the adhesive or the gluing step between joint surfaces 11.

### SUMMARY OF THE INVENTION

In order to solve the foregoing problems, one object of the present invention is to provide the structure of a one-piece-form 3-dimentional bezel and its manufacturing method. The bezel structure utilizes one-piece-form 3-dimentional frame element having the rivet unit and the rivet hole to rivet each other and to utilize the punching step to complete the one-piece-form 3-dimentional bezel.

Another object of the present invention is to provide the structure of a one-piece-form 3-dimentional bezel and its manufacturing method. The present invention unnecessarily utilizes the conventional welding step, the solvent, the adhesive or the gluing step to joint frame elements but only utilizes the common punching equipments to complete the formulation of the one-piece-form 3-dimentional bezel.

The further object of the present invention is to provide the structure of a one-piece-form 3-dimentional bezel and its manufacturing method. While the size of the bezel becomes bigger to cause the difficulty on transporting, the design of the present one-piece-form 3-dimentional bezel may deliver frame elements to the customer end and then perform the punching step and the joint step to assemble the one-piece-form 3-dimentional bezel.

The further object of the present invention is to provide the structure of a one-piece-form 3-dimentional bezel and its manufacturing method. The design of the present one-piece-form 3-dimentional bezel can complete the cutting, punching, and forming process simultaneously so as to simplify the manufacturing process and to increase the manufacturing output.

To achieve the foregoing purposes, one embodiment of the structure of a one-piece-form 3-dimentional of the present invention includes: at least one first 3-dimentional frame element and at least one second 3-dimentional frame element, wherein both first 3-dimentional frame element and second 3-dimentional frame element have a top side and a lateral side with a first angle; a first joint portion and at least one first rivet unit arranged at an edge of the top side of the 3-dimentional first frame element; a second joint portion and at least one second rivet hole arranged at an edge of the top side of the second 3-dimentional frame element, wherein the first rivet unit is protruded on the first joint portion; the second rivet hole is penetrated through the second joint portion; and the first rivet unit of the first joint portion is corresponding penetrating and filling the second rivet hole of the second joint portion so as to align and joint the first 3-dimentional frame element and the second 3-dimentional frame element; a third joint portion and at least one third rivet unit arranged at an edge of the lateral side of the first 3-dimentional frame element; and a fourth joint portion and at least one fourth rivet hole arranged at an edge of the lateral side of the second 3-dimentional frame element, wherein the third rivet unit is protruded on the third joint portion; the fourth rivet hole is penetrated through the fourth joint portion; and the third rivet unit of the third joint portion is corresponding penetrating and filling the fourth rivet hole of the fourth joint portion so as to align and joint the first 3-dimentional frame element and the second 3-dimentional frame element.

Another embodiment of a manufacturing method of a one-piece-form 3-dimentional bezel of the present invention includes the following steps: providing at least one first 3-dimentional frame element and at least one second 3-dimentional frame element, wherein both first 3-dimentional frame element and second 3-dimentional frame element have a top side and a lateral side with a first angle; simultaneously forming a first joint portion and at least one first rivet unit at an edge of the top side of the first 3-dimentional frame element, and forming a third joint portion and at least one third rivet unit at an edge of the lateral side of the first 3-dimentional frame element, wherein the first rivet unit is protruded on the first joint portion and the third rivet unit is protruded on the third joint portion; simultaneously forming a second joint portion and at least one second rivet hole at an edge of the top side of the second 3-dimentional frame element, and forming a fourth joint portion and at least one fourth rivet hole at an edge of the lateral side of the second 3-dimentional frame element, wherein the second rivet hole is penetrated through the second joint portion, and the fourth rivet hole is penetrated through the fourth joint portion; penetrating the first rivet unit of the first joint portion through the second rivet hole of the second joint portion and penetrating the third rivet unit of the third joint portion through the fourth rivet hole of the fourth joint portion to align and joint the first 3-dimentional frame element and the second 3-dimentional frame element; and punching the first rivet unit to fill the second rivet hole, and to punch the third rivet unit to fill the fourth rivet hole so as to tightly joint together with the first 3-dimentional frame element and the second 3-dimentional frame element.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A, FIG. 1B, FIG. 1C, FIG. 1D and FIG. 1E are partial schematic diagrams of the bezel structure of the display panel of the Taiwan Patent Issue No. M285175;

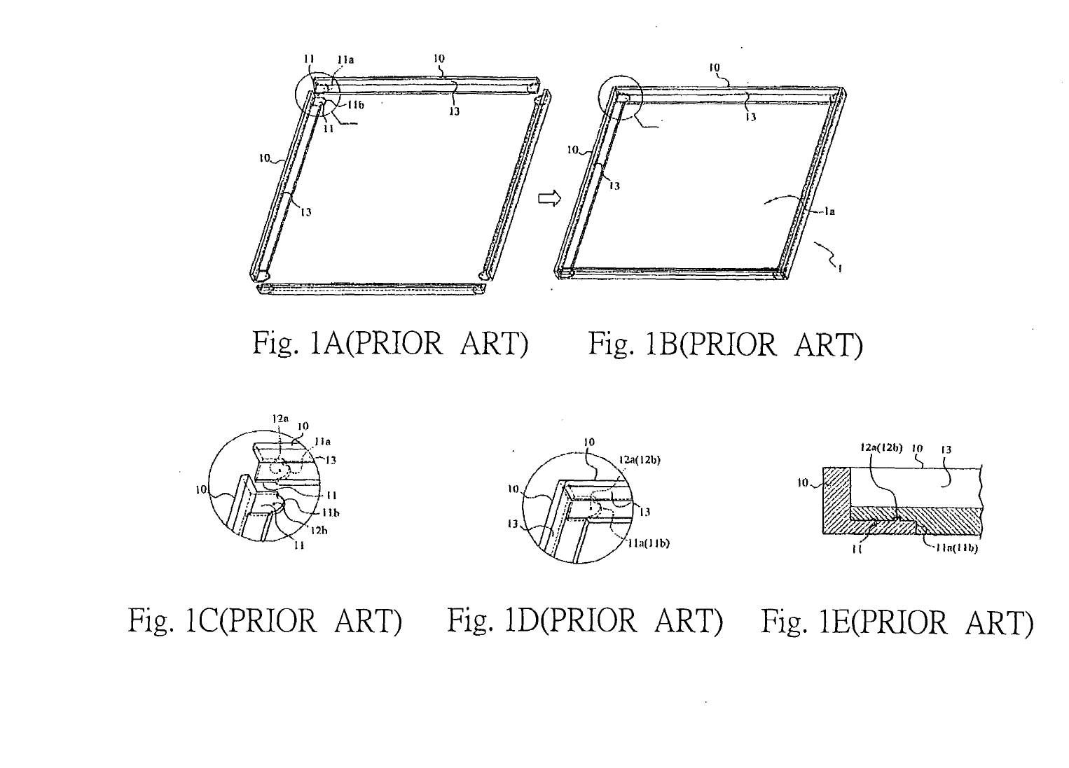

FIG. 2A, FIG. 2B, FIG. 2C and FIG. 2D are partial 3-dimentional schematic diagrams of procedures of the manufacturing method of the one-piece-form 3-dimentional bezel in accordance with one embodiment of the present invention;

FIG. 3A, FIG. 3B, FIG. 3C and FIG. 3D are partial 3-dimentional schematic diagrams of procedures of the manufacturing method of the top side of the one-piece-form 3-dimentional bezel in accordance with one embodiment of the present invention;

FIG. 4A, FIG. 4B, FIG. 4C and FIG. 4D are side-view schematic diagrams according to FIG. 3A, FIG. 3B, FIG. 3C and FIG. 3D;

FIG. 5A, FIG. 5B, FIG. 5C and FIG. 5D are partial side-view schematic diagrams of procedures of the manufacturing method of the lateral side of the one-piece-form 3-dimentional bezel in accordance with one embodiment of the present invention;

FIG. 6 is a partial 3-dimentional schematic diagram of the one-piece-form 3-dimentional bezel in accordance with another embodiment of the present invention;

FIG. 7A is a front view schematic diagram of the one-piece-form 3-dimentional bezel in accordance with one embodiment of the present invention;

FIG. 7B is the cross-sectional view in detail of the portion indicated by the section lines of A-A in FIG. 7A;

FIG. 8A is a front view schematic diagram of the one-piece-form 3-dimentional bezel in accordance with one embodiment of the present invention;

FIG. 8B is the cross-sectional view in detail of the portion indicated by the section lines of B-B in FIG. 8A;

FIG. 9 is a front view schematic diagram of the one-piece-form 3-dimentional bezel in accordance with one embodiment of the present invention;

FIG. 10A is a partial side-view schematic diagram of the top side of the one-piece-form 3-dimentional bezel in accordance with one embodiment of the present invention; and

FIG. 10B is a partial side-view schematic diagram of the lateral side of the one-piece-form 3-dimentional bezel in accordance with one embodiment of the present invention.

### DETAILED DESCRIPTION OF THE INVENTION

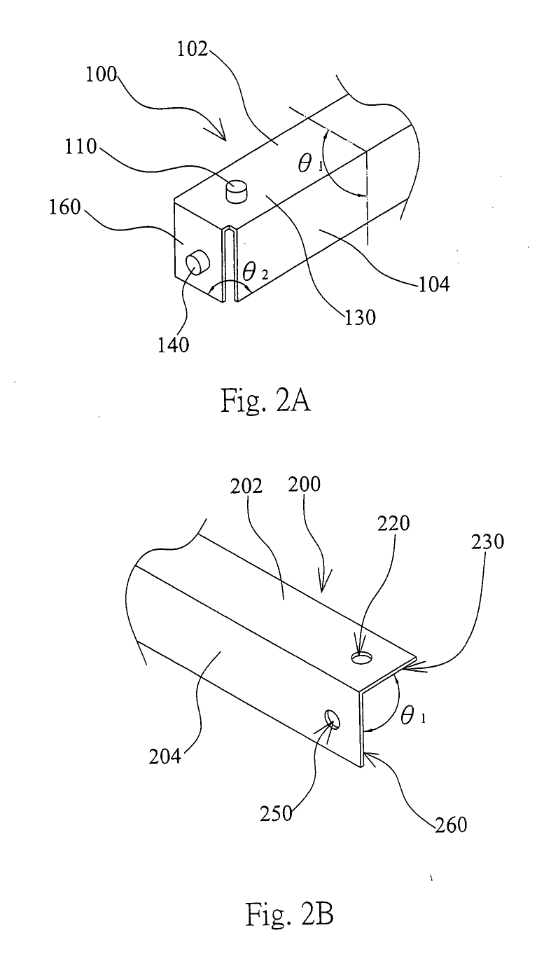

FIG. 2A, FIG. 2B, FIG. 2C and FIG. 2D are partial 3-dimentional schematic diagrams of procedures of the manufacturing method of the one-piece-form 3-dimentional bezel in accordance with one embodiment of the present invention. In the present invention, such as shown in FIG. 2A and FIG. 2B, first, at least one first 3-dimentional frame element 100 and at least one second 3-dimentional frame element 200 is provided, wherein both first 3-dimentional frame element 100 and second 3-dimentional frame element 200 have a top side 102, 202 and a lateral side 104, 204 with a first angle θ₁. A first joint portion 130 and at least one first rivet unit 110 are simultaneously formed at the edge of the top side 102 of the first 3-dimentional frame element 100, and a third joint portion 160 and at least one third rivet unit 140 are simultaneously formed at the edge of the lateral side 104 of the first 3-dimentional frame element 100, wherein, the first rivet unit 110 is protruded on the first joint portion 130 and the third rivet unit 140 is protruded on the third joint portion 160. In this embodiment, shown in FIG. 2A and FIG. 2B, the third joint portion 160 is bent inward from the top side 102 of the first 3-dimentional frame element 100 so as to form a second angle θ₂ between the third joint portion 160 and the lateral side 104 of the first 3-dimentional frame element 100, it is understood that the third joint portion 160 can bend inward from the lateral side 104 of the first 3-dimentional frame element 100 to form the second angle θ₂ between the third joint portion 160 and the lateral side 104. Following, referring to FIG. 2B, a second joint portion 230 and at least one second rivet hole 220 are simultaneously formed at the edge of the top side 202 of the second 3-dimentional frame element 200, and, a fourth joint portion 260 and at least one fourth rivet hole 250 are simultaneously formed at the edge of the lateral side 204 of the second 3-dimentional frame element 200, wherein the second rivet hole 220 and the fourth rivet hole 250 are penetrated through the second joint portion 230 and the fourth joint portion 260 respectively. Following, referring to FIG. 2C, in the present invention, the first rivet unit 110 of the first joint portion 130 is corresponding penetrated through the second rivet hole 220 of the second joint portion 230 and the third rivet unit 140 of the third joint portion 160 is corresponding penetrated through the fourth rivet hole 250 of the fourth joint portion 260 so as to align the first 3-dimentional frame element 100 and the second 3-dimentional frame element 200. Next, referring to FIG. 2D, a punching step is utilized to punch the first rivet unit 110 to fill the second rivet hole 220, and to punch the third rivet unit 140 to fill the fourth rivet hole 250 so as to tightly joint the first 3-dimentional frame element 100 and the second 3-dimentional frame element 200 to become one-piece-form. In the present embodiment, the first 3-dimentional frame element 100 and the second 3-dimentional frame element 200 can complete the cutting, punching, and forming process simultaneously so as to simplify the manufacturing process and to increase the manufacturing output.

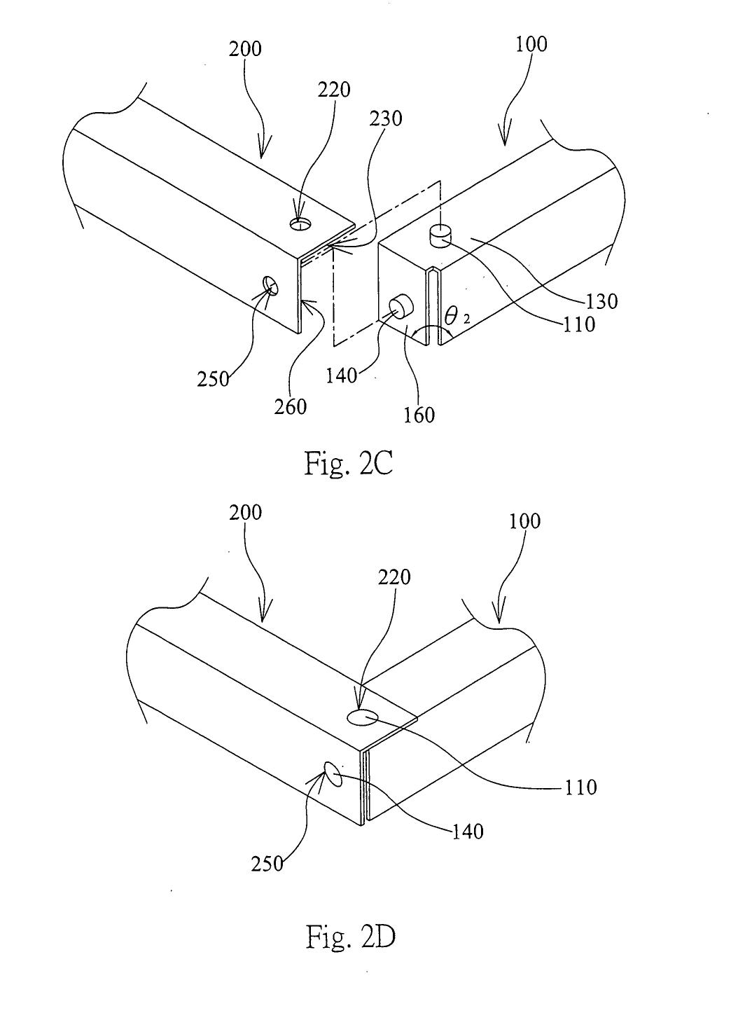

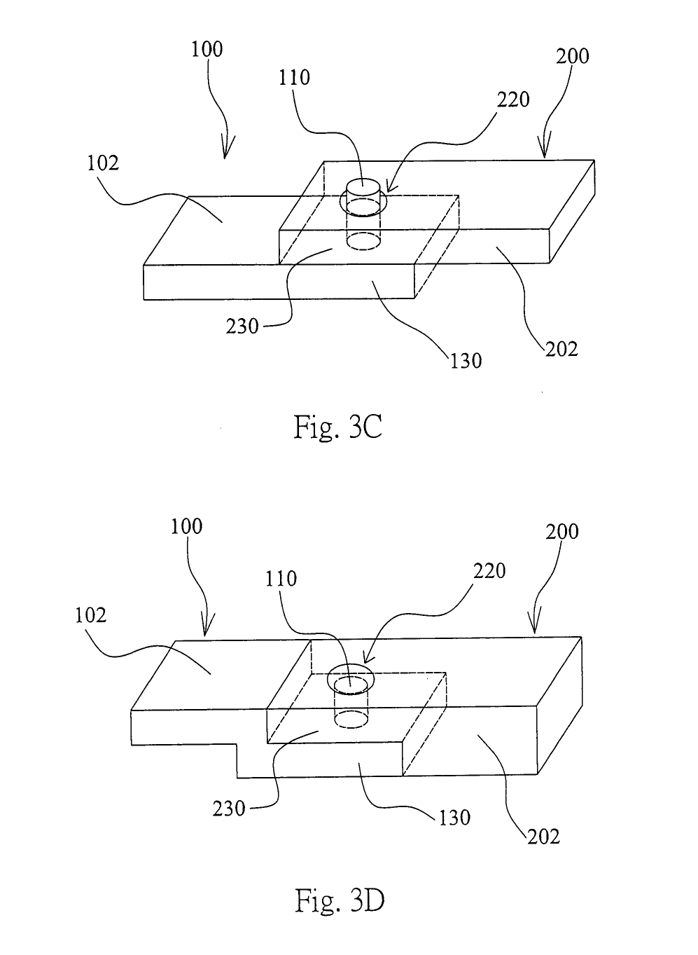

FIG. 3A, FIG. 3B, FIG. 3C, and FIG. 3D are illustrating the steps of jointing the top side 102 of the first 3-dimentional frame element 100 and the top side 202 of the second 3-dimentional frame element 200 in order to clearly describe the steps of jointing the first 3-dimentional frame element 100 and the second 3-dimentional frame element 200. And the steps of jointing the lateral side 104 of the first 3-dimentional frame element 100 and the lateral side 204 of the second 3-dimentional frame element 200 are shown in FIG. 5A, FIG. 5B, FIG. 5C, and FIG. 5D.

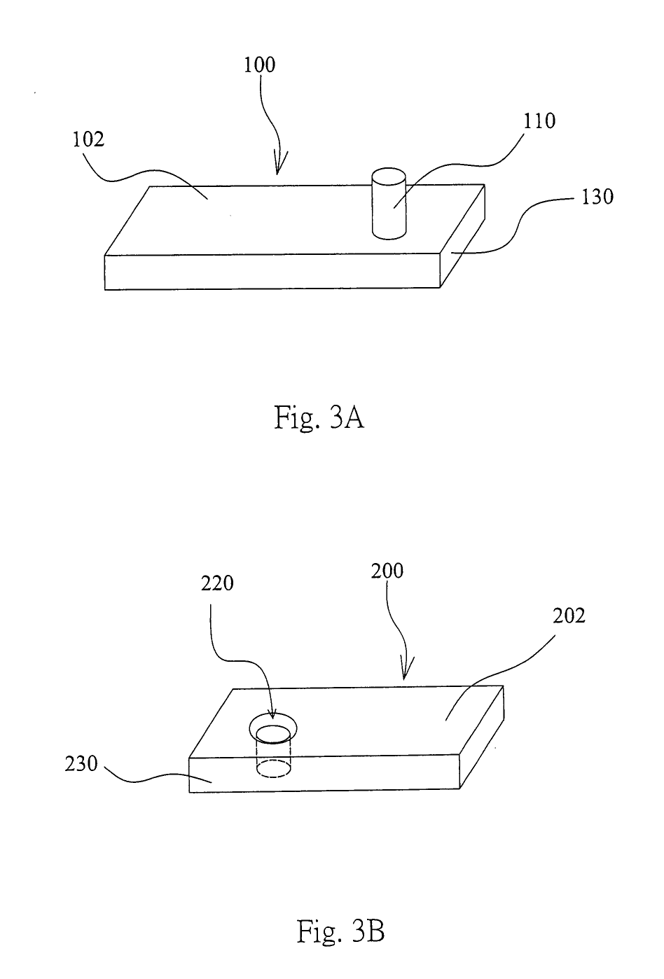

Please refer to FIG. 3A, FIG. 3B, FIG. 3C, FIG. 3D, FIG. 4A, FIG. 4B, FIG. 4C and FIG. 4D at the same time, wherein FIG. 3A, FIG. 3B, FIG. 3C and FIG. 3D are partial 3-dimentional schematic diagrams of procedures of the manufacturing method of the top side of the one-piece-form 3-dimentional bezel in accordance with one embodiment of the present invention, and FIG. 4A, FIG. 4B, FIG. 4C and FIG. 4D are side-view schematic diagrams according to FIG. 3A, FIG. 3B, FIG. 3C and FIG. 3D. In the present invention, first, such as shown in FIG. 3A and FIG. 4A, first, a first joint portion 130 and at least one first rivet unit 110 are simultaneously formed at an edge of a top side 102 of the first 3-dimentional frame element 100, wherein the first joint portion 130 and the first rivet unit 110 are simultaneously formed by a forging step and the first rivet unit 110 is protruded on the first joint portion 130. The first 3-dimentional frame element 100 and the second 3-dimentional frame element 200 are made of metal material and may be a strip-type, a L-type, or a [symbol] -type, and it is understood that the material and the shape is not limited. Following, referring to FIG. 3B and FIG. 4B, at least one second 3-dimentional frame element 200 is provided and a second joint portion 230 and at least one second rivet hole 220 are simultaneously formed at the edge of the top side 202 of the second 3-dimentional frame element 200 by a punching step. Wherein, the second rivet hole 220 is penetrated through the second joint portion 230.

To continue the above explanation and referring to FIG. 3C and FIG. 4C, in the present embodiment, the first rivet unit 110 is corresponding penetrated the second rivet hole 220 of the second joint portion 230 so as to align the first 3-dimentional frame element 100 and the second 3-dimentional frame element 200. Wherein, the second rivet hole 220 is in the shape of an upside wide and downside narrow hole, such as a funnel type hole. The first rivet unit 110 is jointed the second rivet hole 220 from the narrow downside to the wide upside. Then, referring to FIG. 3D and FIG. 4D, a punching step is utilized to punch the first rivet unit 110 to fill the second rivet hole 220 to tightly join the first 3-dimentional frame element 100 and the second 3-dimentional frame element 200 to become one-piece-form.

Next, FIG. 5A, FIG. 5B, FIG. 5C, and FIG. 5A are illustrating the joint steps of the lateral side 104, 204 of the first 3-dimentional frame element 100 and the second 3-dimentional frame element 200, wherein the 3-dimentional schematic diagram of the lateral side is as the same as the top side, so will not describe it again. Referring to FIG. 5A, first, a third joint portion 160 and at least one third rivet unit 140 are simultaneously formed at the edge of the lateral side 104 of the first 3-dimentional frame element 100 by a forging step and the third rivet unit 140 is protruded on the third joint portion 160. Following, referring to FIG. 5B, at least one second 3-dimentional frame element 200 is provided and a fourth joint portion 260 and at least one fourth rivet hole 250 are simultaneously formed at the edge of the lateral side 204 of the second 3-dimentional frame element 200 by a punching step, wherein the fourth rivet hole 250 is penetrated through the fourth joint portion 260.

Referring to FIG. 5C, in the present invention, the third rivet unit 140 of the third joint portion 160 is corresponding penetrated the fourth rivet hole 250 of the fourth joint portion 260 so as to align the first 3-dimentional frame element 100 and the second 3-dimentional frame element 200. Wherein, the fourth rivet hole 250 is in the shape of an upside wide and downside narrow hole, such as a funnel type hole, and the third rivet unit 140 is jointed the fourth rivet hole 250 from the narrow downside to the wide upside. Then, referring to FIG. 5D, a punching step is utilized to punch the third rivet unit 140 to fill the fourth rivet hole 250 to tightly joint the first 3-dimentional frame element 100 and the second 3-dimentional frame element 200 to become one-piece-form.

Please refer to FIG. 2C, FIG. 4D, and FIG. 5D at the same time, in the present embodiment, the one-piece-form 3-dimentional bezel structure is composed of at least one first 3-dimentional frame element 100 and at least one second 3-dimentional frame element 200. The first 3-dimentional frame element 100 and the second 3-dimentional frame element 200 are jointed together by utilizing the first joint portion 130 and the second joint portion 230 of the top side 102, 202 thereof and by utilizing the third joint portion 160 and the fourth joint portion 260 of the lateral side 104, 204 thereof. The first rivet unit 110 is protruded on the first joint portion 130 and the second rivet hole 220 is penetrated through the second joint portion 230, such as shown in FIG. 4D. The first rivet unit 110 of the first joint portion 130 penetrates and fills the second rivet hole 220 of the second joint portion 230. In the present embodiment, the third joint portion 160 is bent inward from the lateral side 104 of the first 3-dimentional frame element 100 so as to form the second angle θ₂ between the third joint portion 160 and the lateral side 104. The third rivet unit 140 is protruded on the third joint portion 160, wherein the second angle θ₂ is an adequate angle so as to align the lateral side 104 of the first 3-dimentional frame element 100 and the lateral side 204 of the second 3-dimentional frame element 200 to strengthen the mechanism strength of the 3-dimentional frame element after the rivet process. And, the fourth rivet hole 250 is penetrated through the fourth joint portion 260, such as shown in FIG. 5D, the lateral side 104 of the first frame 3-dimentional element 100 and the lateral side 204 of the second 3-dimentional frame element 200 are aligned by jointing the third rivet unit 140 of the third joint portion 160 with the fourth rivet hole 250 of the fourth joint portion 260 and filling the fourth rivet hole 250. Wherein, the second rivet hole 220 is in the shape of an upside wide and downside narrow hole, such as a funnel type hole, and the first rivet unit 110 is jointed the second rivet hole 220 from the narrow downside to the wide upside. Besides, the fourth rivet hole 250 can be in the shape of an upside wide and downside narrow hole, such as a funnel type hole too, and the third rivet unit 140 is jointed the fourth rivet unit 250 from the narrow downside to the wide upside.

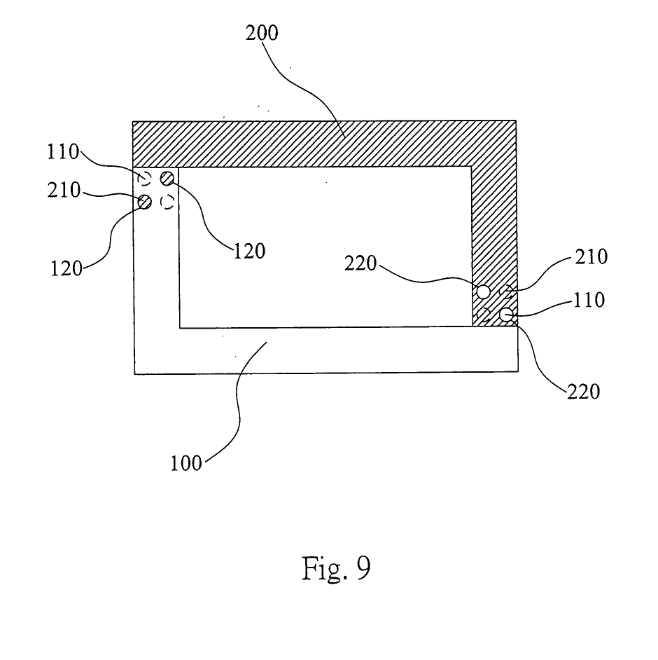

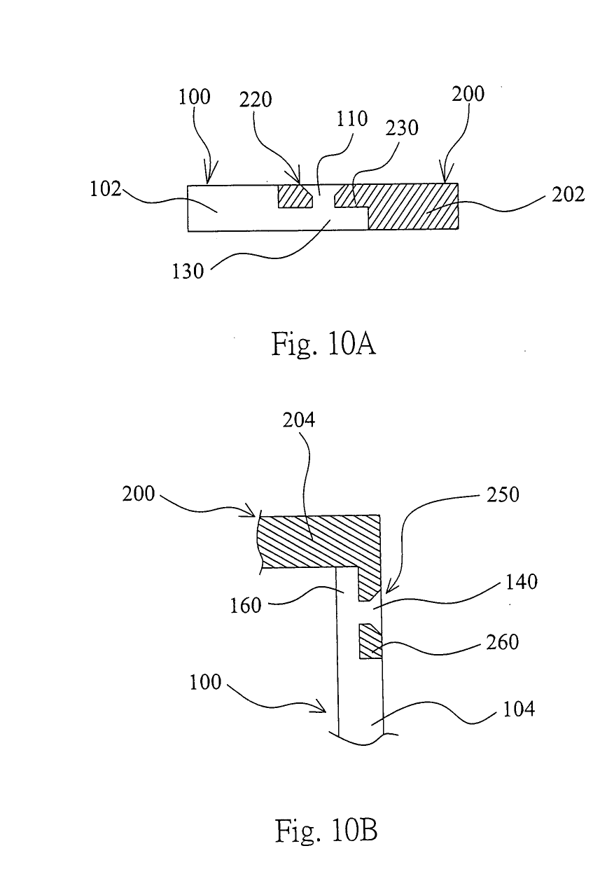

To continue the above explanation and referring to FIG. 10A and FIG. 10B, in the present embodiment, the combination thickness of the first joint portion 130 and the second joint portion 230 is equal to the thickness of the top side 102, 202 of the first 3-dimentional frame element 100 and the second 3-dimentional frame element 200. And the combination thickness of the third joint portion 160 and the fourth joint portion 260 is equal to the thickness of the lateral side 104, 204 of the first 3-dimentional frame element 100 and the second 3-dimentional frame element 200.

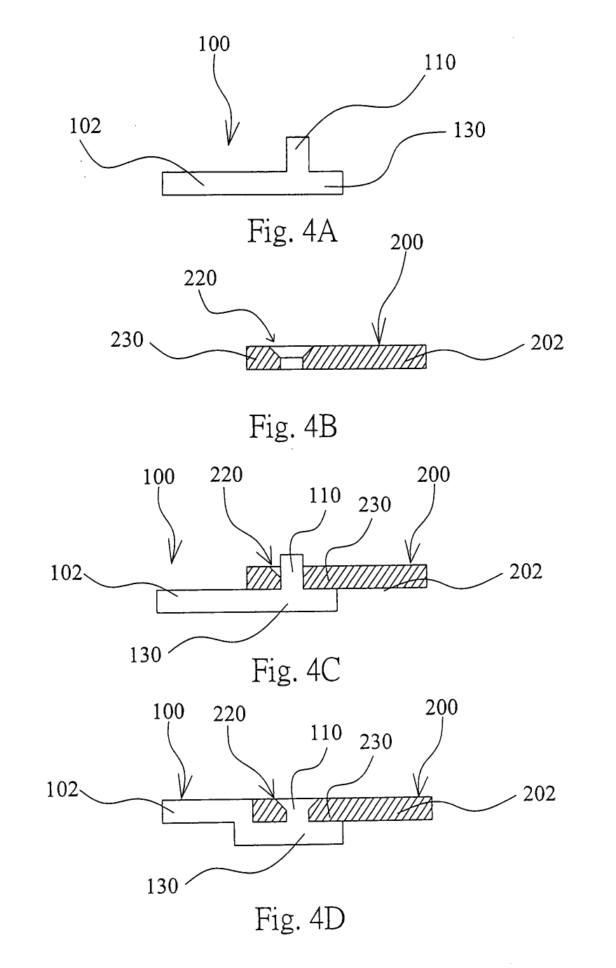

In another embodiment, shown in FIG. 6, the fourth joint portion 260 of the second 3-dimentional frame element 200 can be arranged on the second 3-dimentional frame element 200 and to form a second angle θ₂ between the fourth joint portion 260 and the lateral side 204, wherein the second angle θ₂ is an adequate angle so as to align the fourth rivet hole 250 and the third rivet unit 140 of the third joint portion 160 so as to strengthen the mechanism strength of the 3-dimentional frame element after the rivet process. Shown in FIG. 6, the fourth joint portion 260 is bent inward from the top side 202 of the second 3-dimentional frame element 200 and to form a second angle θ₂ between the fourth joint portion 260 and the lateral side 204, but not limited. In another embodiment, the fourth joint portion 260 can be bent inward from the lateral side 204 of the second 3-dimentional frame element 200 and to form a second angle θ₂ between the fourth joint portion 260 and the lateral side 204. The first rivet unit 110 of the first joint portion 130 is corresponding penetrated the second rivet hole 220 of the second joint portion 230 and filled the second rivet hole 220, and the third rivet unit 140 of the third joint portion 160 is corresponding penetrated the fourth rivet hole 250 of the fourth joint portion 260 and filled the fourth rivet hole 250 so as to align the top side 102, 202 and the lateral side 104, 204 of the first 3-dimentional frame element 100 and the second 3-dimentional frame element 200.

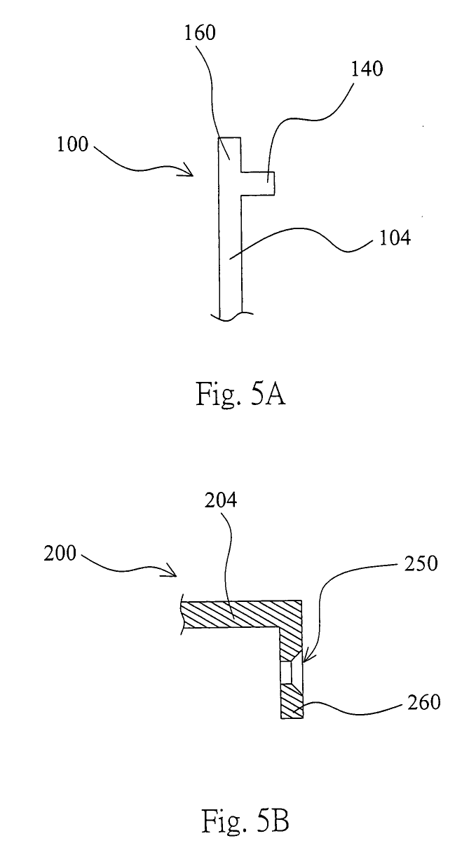

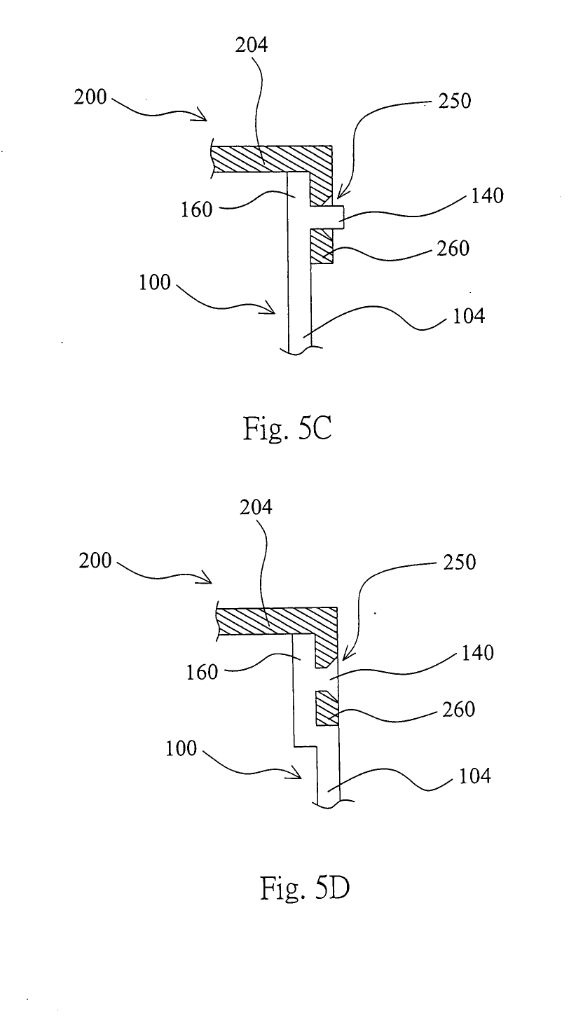

Next, referring to FIG. 7A, the first 3-dimentional frame element 100 and the second 3-dimentional frame element 200 are strip-type 3-dimentional frame elements to assemble a 3-dimentional rectangular bezel. Shown in FIG. 7B, two first rivet units 110 of the first joint portion 130 are penetrate and fill two second rivet holes 220 of the second joint portion 230, and two third rivet units 140 of the third joint portion 160 of the lateral side 104 are corresponding penetrate and fill two fourth rivet holes 250 of the fourth joint portion 260 of the lateral side 204 so as to align the first 3-dimentional frame element 100 and the second 3-dimentional frame element 200.

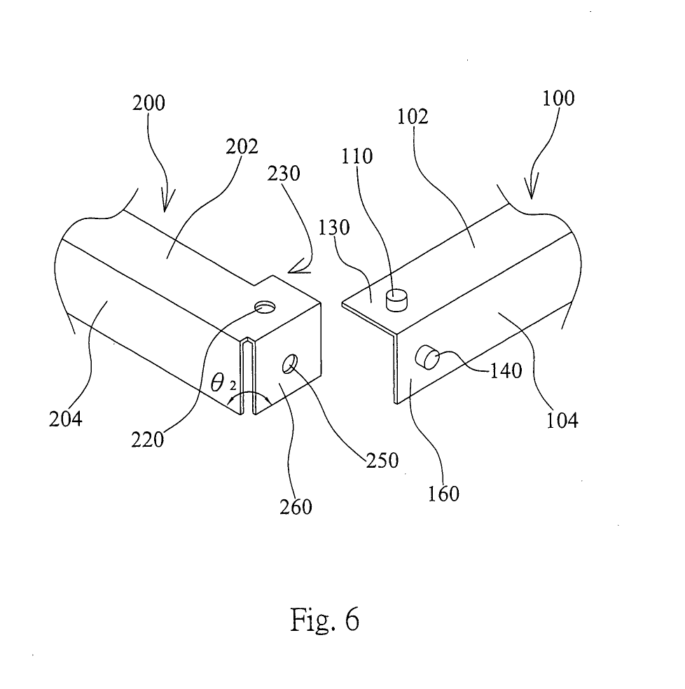

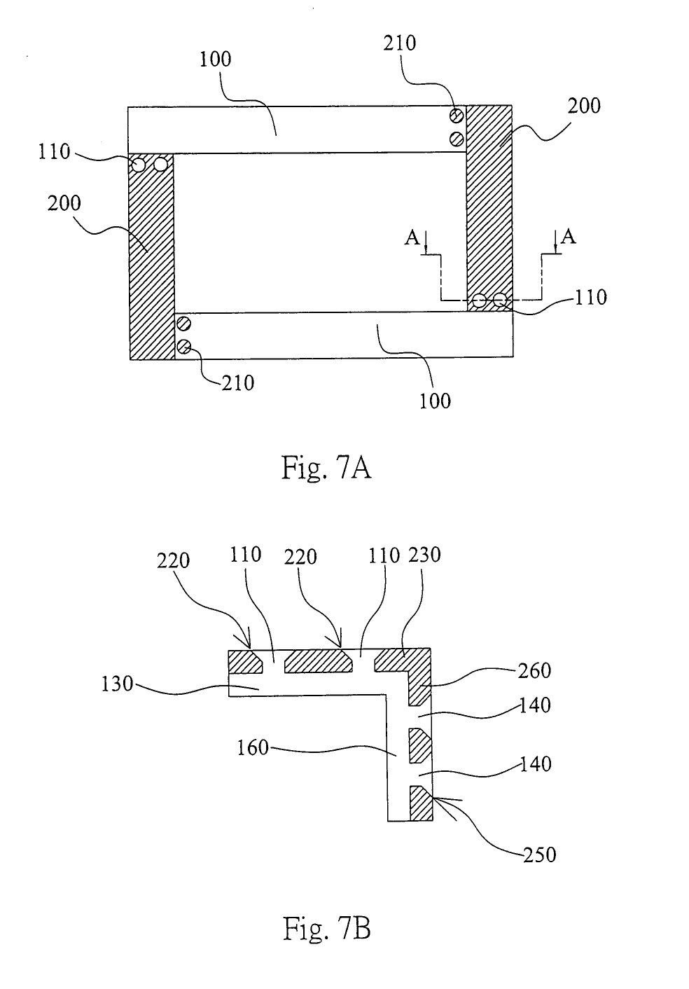

Referring to FIG. 8A, it is a front view schematic diagram of the one-piece-form 3-dimentional bezel in accordance with one embodiment of the present invention. In the present invention, the first 3-dimentional frame element 100 and the second 3-dimentional frame element 200 are [symbol] -type 3-dimentional frame elements to assemble a 3-dimentional rectangular bezel. Shown in FIG. 8B, on the first joint portion 130, besides the first rivet unit 110 protruding arranged thereon, there can further arrange at least one first rivet hole 120 on the first joint portion 130 by utilizing a punching step. At the correspondingly position, at least one second rivet unit 210 on the second joint portion 120 by utilizing a forging step to corresponding penetrating the first rivet hole 120 and the first rivet unit 110 is penetrating through the second rivet hole 220, further, on the third joint portion 160, besides the third rivet unit 140 protruding arranged thereon, there can further arrange at least one third rivet hole 150 on the third joint portion 160 by utilizing a punching step. At the correspondingly position, at least one fourth rivet unit 240 on the fourth joint portion 260 by utilizing a forging step to corresponding penetrating the third rivet hole 150 and the third rivet unit 140 is penetrating through the fourth rivet hole 250 so as the first 3-dimentional frame element 100 and the second 3-dimentional frame element 200 can be tightly align and joint with each other.

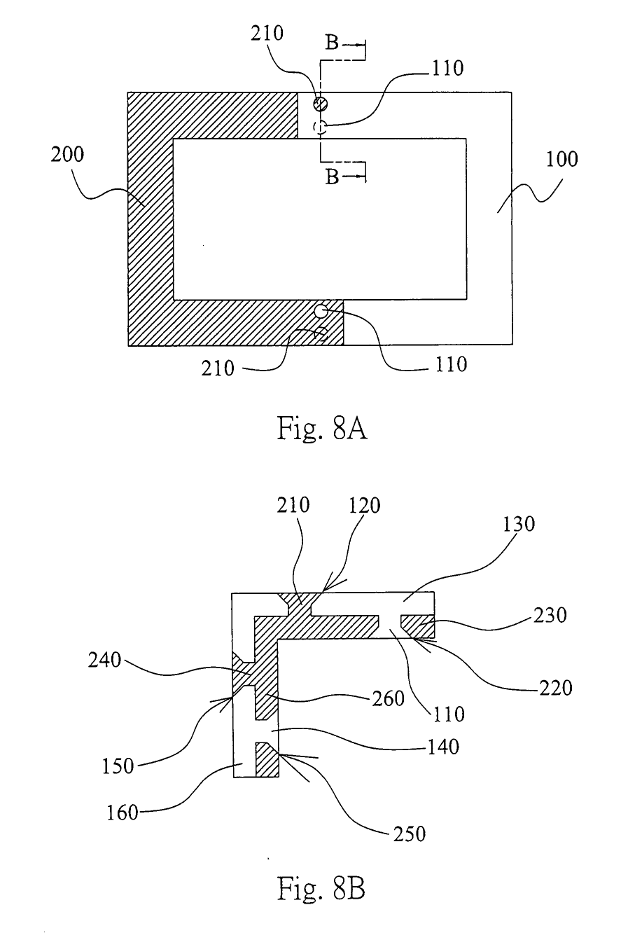

Further, please refer to FIG. 9, in another embodiment, the first 3-dimentional frame element 100 and the second 3-dimentional frame element 200 are L-type 3-dimentional frame elements to assemble the rectangular bezel and utilizes a plurality of first rivet holes 120 with a plurality of first rivet units 110 and a plurality of second rivet holes 220 with a plurality of second rivet units 210 to tightly align and joint with each other on the top side. And, further utilizing a plurality of third rivet holes (not shown) with a plurality of third rivet units (not shown) and a plurality of fourth rivet holes (not shown) with a plurality of fourth rivet units (not shown) to tightly align and joint with each other on the lateral side.

According to the above description, one feature of the present invention is to utilize different shape 3-dimentional frame elements and arrange rivet unit and rivet hole at the edge of the top side and the lateral side of the 3-dimentional frame element to tightly align and joint 3-dimentional frame elements to form the one-piece-form 3-dimentional bezel. The manufacturing procedure is simple and easy without any extra compound, such as the adhesive and the frame-jointing element, and the 3-dimentional bezel formation by the riveting step is stable and can be completed by the original exist equipments.

To sum up the foregoing descriptions, the present invention is to provide the structure of a one-piece-form 3-dimentional bezel and its manufacturing method. The bezel structure utilizes one-piece-form 3-dimentional frame element having the rivet and the rivet hole to rivet each other and to utilize the punching step to complete the one-piece-form 3-dimentional bezel. The present invention unnecessarily utilizes the conventional welding step, the solvent, the adhesive or the gluing step to joint frame elements but only utilizes the common punching equipments to complete the formulation of the one-piece-form 3-dimentional bezel. While the size of the bezel becomes bigger to cause the difficulty on transporting, the design of the present one-piece-form bezel may deliver frame elements to the customer end and then perform the punching step and the joint step to assemble the one-piece-form bezel. Furthermore, the design of the present one-piece-form 3-dimentional bezel can complete the cutting, punching, and forming process simultaneously so as to simplify the manufacturing process and to increase the manufacturing output.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

What is claimed is:

1. A structure of a one-piece-form 3-dimentional bezel, comprising:
At least one first 3-dimentional frame element and at least one second 3-dimentional frame element, wherein both said first 3-dimentional frame element and said second 3-dimentional frame element have a top side and a lateral side with a first angle;
a first joint portion and at least one first rivet unit arranged at an edge of said top side of said first 3-dimentional frame element;
a second joint portion and at least one second rivet hole arranged at an edge of said top side of said second 3-dimentional frame element, wherein
said first rivet unit is protruded on said first joint portion;
said second rivet hole is penetrated through said second joint portion;and
said first rivet unit is corresponding penetrating and filling said second rivet hole so as to align and joint said first 3-dimentional frame element and said second 3-dimentional frame element;
a third joint portion and at least one third rivet unit arranged at an edge of said lateral side of said first 3-dimentional frame element; and
a fourth joint portion and at least one fourth rivet hole arranged at an edge of said lateral side of said second 3-dimentional frame element, wherein
said third rivet unit is protruded on said third joint portion;
said fourth rivet hole is penetrated through said fourth joint portion;and
said third rivet unit is corresponding penetrating and filling said fourth rivet hole so as to align and joint said first 3-dimentional frame element and said second 3-dimentional frame element.

2. The structure of a one-piece-form 3-dimentional bezel according to claim 1, wherein said third joint portion and said lateral side of said first 3-dimentional frame element are at a second angle.

3. The structure of a one-piece-form 3-dimentional bezel according to claim 1, wherein said fourth joint portion and said lateral side of said second 3-dimentional frame element are at a second angle.

4. The structure of a one-piece-form 3-dimentional bezel according to claim 1, wherein said second rivet hole and said fourth rivet hole are funnel type holes or upside wide and downside narrow holes.

5. The structure of a one-piece-form 3-dimentional bezel according to claim 1, wherein a combination thickness of said first joint portion and said second joint portion is equal to a thickness of said top side of said first 3-dimentional frame element and said second 3-dimentional frame element, and a combination thickness of said third joint portion and said fourth joint portion is equal to a thickness of said lateral side of said first 3-dimentional frame element and said second 3-dimentional frame element.

6. The structure of a one-piece-form 3-dimentional bezel according to claim 1, wherein said first joint portion is further arranged at least one first rivet hole thereon.

7. The structure of a one-piece-form 3-dimentional bezel according to claim 6, wherein said second joint portion is further arranged at least one second rivet unit thereon penetrating said first rivet hole.

8. The structure of a one-piece-form 3-dimentional bezel according to claim 1, wherein said third joint portion is further arranged at least one third rivet hole thereon.

9. The structure of a one-piece-form 3-dimentional bezel according to claim 8, wherein said fourth joint portion is further arranged at least one fourth rivet unit thereon penetrating said third rivet hole.

10. The structure of a one-piece-form 3-dimentional bezel according to claim 1, wherein said first 3-dimentional frame element and said second 3-dimentional frame element are made of metal.

11. The structure of a one-piece-form 3-dimentional bezel according to claim 1, wherein said first 3-dimentional frame element and said second 3-dimentional frame element is a strip-type, a L-type or a [symbol] -type.

12. A manufacturing method of a one-piece-form 3-dimentional bezel, comprising the following steps:
providing at least one first 3-dimentional frame element and at least one second 3-dimentional frame element, wherein both said first 3-dimentional frame element and said second 3-dimentional frame element have a top side and a lateral side with a first angle;
simultaneously forming a first joint portion and at least one first rivet unit at an edge of said top side of said first 3-dimentional frame element, and forming a third joint portion and at least one third rivet unit at an edge of said lateral side of said first 3-dimentional frame element, wherein said first rivet unit is protruded on said first joint portion and said third rivet unit is protruded on said third joint portion;
simultaneously forming a second joint portion and at least one second rivet hole at an edge of said top side of said second 3-dimentional frame element, and forming a fourth joint portion and at least one fourth rivet hole at an edge of said lateral side of said second 3-dimentional frame element, wherein said second rivet hole is penetrated through said second joint portion, and said fourth rivet hole is penetrated through said fourth joint portion;
penetrating said first rivet unit through said second rivet hole and penetrating said third rivet unit through said fourth rivet hole to align and joint said first 3-dimentional frame element and said second 3-dimentional frame element; and
punching said first rivet unit to fill said second rivet hole and to punch said third rivet unit to fill said fourth rivet hole to tightly joint together with said first 3-dimentional frame element and said second 3-dimentional frame element.

13. The manufacturing method of a one-piece-form 3-dimentional bezel according to claim 12, wherein said third joint portion and said lateral side of said first 3-dimentional frame element are at a second angle.

14. The manufacturing method of a one-piece-form 3-dimentional bezel according to claim 12, wherein said fourth joint portion and said lateral side of said second 3-dimentional frame element are at a second angle.

15. The manufacturing method of a one-piece-form 3-dimentional bezel according to claim 12, further comprising a step of utilizing a forging step to from said first joint portion, said first rivet unit, said third joint portion, and said third rivet unit.

16. The manufacturing method of a one-piece-form 3-dimentional bezel according to claim 12, further comprising a step of utilizing a punching step to form said second joint portion, said rivet hole, said fourth joint portion and said fourth rivet hole.

17. The manufacturing method of a one-piece-form 3-dimentional bezel according to claim 12, further comprising a step of utilizing a punching step to form at least one first rivet hole at said first joint portion and to form at least one third rivet hole at said third joint portion.

18. The manufacturing method of a one-piece-form 3-dimentional bezel according to claim 17, further comprising a step of utilizing a forging step to form at least one second rivet unit at said second joint portion, and at least one fourth rivet unit at said fourth joint portion to corresponding penetrate said third rivet hole respectively.

19. The manufacturing method of a one-piece-form 3-dimentional bezel according to claim 12, wherein said first 3-dimentional frame element and said second 3-dimentional frame element are made of metal.

20. The manufacturing method of a one-piece-form 3-dimentional bezel according to claim 12, wherein said first 3-dimentional frame element and said second 3-dimentional frame element is a strip-type, a L-type or a [symbol] -type.

21. The manufacturing method of a one-piece-form 3-dimentional bezel according to claim 12, wherein said second rivet hole and said fourth rivet hole are funnel type holes.

22. The manufacturing method of a one-piece-form 3-dimentional bezel according to claim 12, wherein said second rivet hole and said fourth rivet hole are upside wide and downside narrow holes.
